(19) United States
(12) Patent Application Publication
(10) Pub. No.: US 2024/0213768 A1
(43) Pub. Date: Jun. 27, 2024

(54) AN ELECTRICAL APPLIANCE

(71) Applicant: Breville USA, Inc., Torrance, CA (US)

(72) Inventor: Douglas Eugene BALDWIN, Torrance, CA (US)

(73) Assignee: Breville USA, Inc., Torrance, CA (US)

(21) Appl. No.: 18/555,739

(22) PCT Filed: Apr. 22, 2022
(86) PCT No.: PCT/IB2022/053758

§ 371 Date: Oct. 17, 2023

(30) Foreign Application Priority Data
Apr. 23, 2021 (AU) 2021901207

(51) Int. Cl. H02H 9/02; G05B 13/02; G05D 23/19; H02J 3/14

(52) U.S. Cl. CPC H02H 9/02; G05B 13/0205; G05D 23/1928; H02J 3/14; H02J 2310/14

(57) ABSTRACT

An electrical appliance comprising: a plurality of electrical loads, each electrical load being powered from a common power source; a controller including a processor coupled to a memory, wherein the memory has stored therein a sequence of numbers and a plurality of numerical ranges, each numerical range being associated with a respective electrical load from the plurality of electrical loads; and a plurality of switches, each electrical switch being electrically coupled to the power source, the controller, and a respective electrical load of the plurality of electrical loads; wherein the appliance is configured to iteratively: select, by the controller, a plurality of numbers from the sequence of numbers; generate, by the controller, a switching signal for any electrical load of the plurality of electrical loads which is associated with a respective numerical range which includes a number from the plurality of numbers; and activate, for each switching signal, a respective switch of the plurality of switches to electrically connect the respective electrical load to the power source over a period of time.

### TECHNICAL FIELD

The present invention relates to an electrical appliance, and in particular to controlling electrical loads of the electrical appliance.

### BACKGROUND

Any discussion of the prior art throughout the specification should in no way be considered as an admission that such prior art is widely known or forms part of the common general knowledge in the field.

Certain appliances may include a plurality of high-power electrical loads. To operate an appliance (such as a compact oven) with different power profiles for reaching a set temperature, a dimming circuit can be used to control the oven's heating elements to reach the required temperature. This type of dimming requires an EMC (electromagnetic compatibility) filter circuit so that the dimming circuit does not cause electromagnetic interference affecting mains power and appliances on the same electric circuit. The type of EMC solutions required can be costly.

Another way of providing different power profiles is to switch the heating elements on and off for varying times. Generally, this has been achieved using a lookup table which is stored in memory of the appliance. A plurality of switching patterns are stored in the lookup table. Each switching pattern is used by a controller to controllably switch on and off the electrical loads to achieve a predefined power profile for the appliance.

Whilst generating a lookup table for controlling two electrical loads is achievable, the process of generating such a lookup table for switching three or more electrical loads to achieve different power profiles for the appliance can be quite difficult. In particular, the lookup table becomes quite lengthy and can negatively impact memory constraints for the appliance for three or more electrical loads. Moreover, the complexity of the generation of the lookup table is further dependent on the number of power profiles to be provided per electrical load. Generally, users of an appliance desire refined control (for example temperature or motor speed etc.), thus the complexity of the generation of the lookup table increases which further negatively impacts on the length of the table and the memory usage of the appliance.

Other constraints may impact the generation of such a table.

For example, there may be regulatory requirements in terms of the amount of electrical power which the electrical loads of the appliance can consume. Thus, for example, simultaneous operation of all the high-power electrical loads may not be possible given this constraint, therefore the switching sequences of the table must be generated in a manner which complies with this regulatory and/or practical constraints such as constraints for power cords and residential circuits.

In some instances it has been observed that switching high-power electrical loads to control the power consumption can cause a visible “flicker” in lights located within the device or connected on the same mains power circuit. Thus, this further constraint can further complicate the generation of the switching sequences.

### SUMMARY

It is an object of the present invention to overcome or ameliorate at least one of the disadvantages of the prior art, or to provide a useful alternative.

An electrical appliance comprising: a plurality of electrical loads, each electrical load being powered from a common power source: a controller including a processor coupled to a memory, wherein the memory has stored therein a sequence of numbers and a plurality of numerical ranges, each numerical range being associated with a respective electrical load from the plurality of electrical loads: and a plurality of switches, each electrical switch being electrically coupled to the power source, the controller, and a respective electrical load of the plurality of electrical loads: wherein the appliance is configured to iteratively: select, by the controller, a plurality of numbers from the sequence of numbers; generate, by the controller, a switching signal for any electrical load of the plurality of electrical loads which is associated with a respective numerical range which includes a number from the plurality of numbers: and activate, for each switching signal, a respective switch of the plurality of switches to electrically connect the respective electrical load to the power source over a period of time.

In certain embodiments, the plurality of numbers includes n numbers such that a maximum power consumption via simultaneous activation of n electrical loads from the plurality of electrical loads does not exceed a power threshold for the electrical appliance.

In certain embodiments, the sequence of numbers is a sequence of tuples.

In certain embodiments, each tuple includes n tuple elements.

In certain embodiments, the sequence of numbers is generated based on a low-discrepancy sequence.

In certain embodiments, the low-discrepancy sequence is a Halton sequence.

In certain embodiments, the sequence is based on a stochastic or pseudo-random sequence.

In certain embodiments, the sequence of numbers is stored in a non-volatile manner in the memory.

In certain embodiments, the sequence of numbers is dynamically generated by the processor and stored in a volatile manner in the memory.

In certain embodiments, electrical power consumed by the electrical appliance has a short term flicker severity less than or equal to 1.0.

In certain embodiments, the appliance includes one or more user input devices for setting operation of at least some of the electrical loads of the plurality of loads, wherein the processor is configured to dynamically scale the plurality of numerical ranges based on one or more input signals generated by the one or more user input devices.

In certain embodiments, the controller is configured to dynamically scale the plurality of numerical ranges based on one or more PID control variables generated by a PID controller, wherein the PID controller is part of the controller or in electrical communication with the controller.

In certain embodiments, the plurality of electrical loads include one or more heating elements, wherein the electrical appliance further includes one or more temperature sensors for measuring a temperature of a medium or object heated by at least some of the one or more heating elements, wherein the one or more input signals include one or more temperature measurement signals generated by the one or more temperature sensors.

In certain embodiments, the plurality of electrical loads include one or more motors, wherein the electrical appliance further includes one or more tachometers for at least some of the one or more motors, wherein the one or more input signals include one or more tachometer measurement signals generated by the one or more tachometers.

In certain embodiments, the electrical appliance further includes a zero-crossing detector, wherein the controller is configured to activate, for each switching signal, the respective switch of the plurality of switches in response to receiving a zero-crossing detection signal from the zero-crossing detector.

In certain embodiments, the electrical appliance is a kitchen appliance.

In another aspect, there is provided an electrical appliance comprising: a controller including a processor coupled to a memory, wherein the memory has stored therein a sequence of numbers and a plurality of numerical ranges: a plurality of electrical load elements, wherein at least one of the plurality of electrical load elements is associated with one of the stored plurality of numerical ranges, wherein the controller is configured to: read a first portion of the sequence, wherein the first portion comprises at least one number, determine the numerical range in which the first portion of the sequence falls therein, and based on the determination, selectively power at least one of the electrical load elements.

In certain embodiments, the sequence of numbers is a sequence of tuples.

In certain embodiments, the sequence of numbers is generated based on a low-discrepancy sequence.

In certain embodiments, the low-discrepancy sequence is a Halton sequence.

In certain embodiments, the Halton sequence is a base n, Halton sequence, wherein n is equal to a number of electrical loads within the plurality of electrical loads.

In certain embodiments, the sequence of numbers is stored in a non-volatile manner in the memory.

In certain embodiments, the sequence of numbers is dynamically generated by the processor and stored in a volatile manner in the memory.

In certain embodiments, a second portion of the sequence of numbers is sequentially read at a next zero crossing point.

In certain embodiments, a second portion of the sequence of numbers, comprising at least one number, is sequentially read after predetermined time period has elapsed.

In certain embodiments, the sequence is associated with a short-term flicker severity of less than 1.0.

In certain embodiments, the plurality of numerical ranges is fixed.

In certain embodiments, the plurality of numerical ranges is set by the processor, based on a current configuration of the electrical appliance.

### BRIEF DESCRIPTION OF THE DRAWINGS

A preferred embodiment of the invention will now be described, by way of example only, with reference to the accompanying drawings in which:

FIG. 1 is a schematic diagram representing an example of an electrical appliance.

FIG. 2 is a flowchart representing a method performed by the electrical appliance of FIG. 1.

FIG. 3A is a functional block diagram representing the electrical appliance of FIG. 1.

FIG. 3B is a schematic block diagram of a controller of the electrical appliance of FIG. 1.

FIG. 4 is a graph showing an example of consumed power for a plurality of electrical loads over time for the electrical appliance of FIG. 1 using a first switching technique.

FIG. 5 is a schematic diagram representing a further example of an electrical appliance.

FIG. 6 is a graph showing a further example of consumed power for a plurality of electrical loads over time for the electrical appliance of FIG. 3 using a second switching technique.

FIG. 7 is a graph showing a further example of consumed power for a plurality of electrical loads over time for the electrical appliance of FIG. 3 using a third switching technique.

FIG. 8A is a graph showing a control variable varying according to time for controlling activation of a plurality of electrical loads of the electrical appliance of FIG. 3.

FIG. 8B is graph showing a further example of consumed power for a plurality of electrical loads of the electrical appliance according to FIG. 3 and based on the control variable as depicted in FIG. 8A and based on the third switching technique.

### DETAILED DESCRIPTION

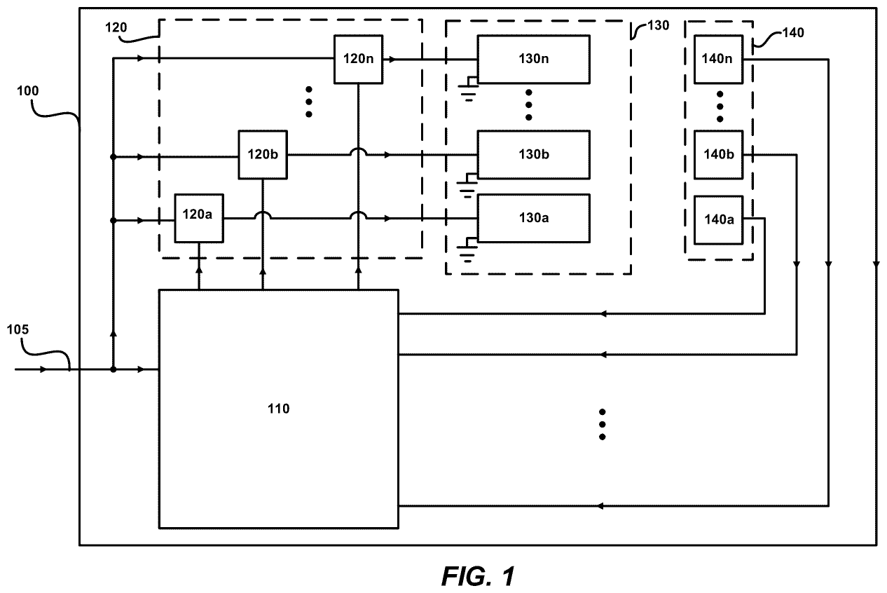

Referring to FIG. 1 there is shown a schematic diagram of an example of an electrical appliance 100.

The electrical appliance 100 includes a plurality of electrical loads 130. Each electrical load 130a, 130b, . . . 130n, being selectively powered from a common power source 105. In one form, the power source 105 could be an alternating current (AC) power source. In another form, the power source may be a direct current (DC) power source.

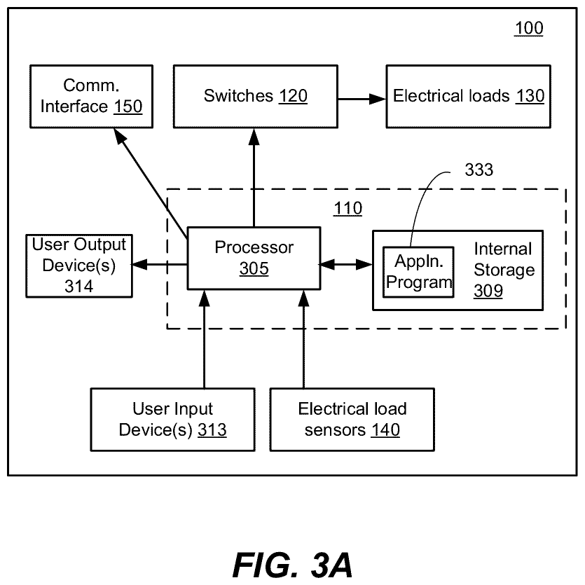

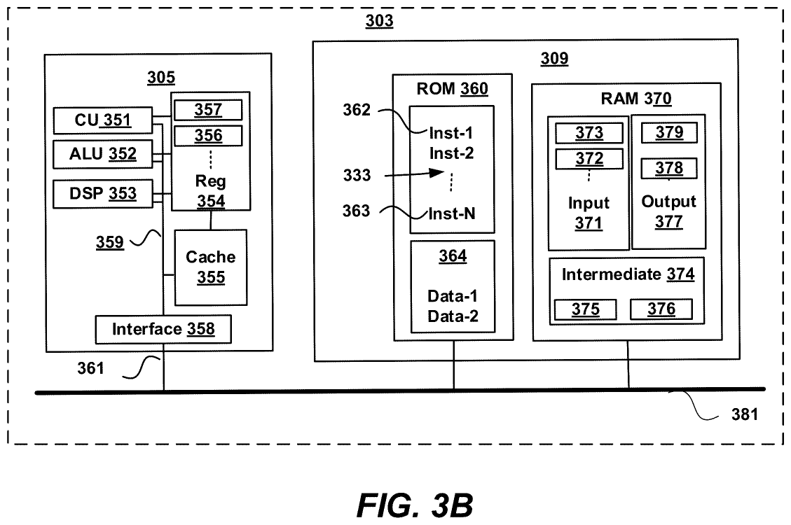

The electrical appliance 100 further includes a controller 110 including a processor 305 (see FIG. 3A) coupled to a memory 309 (see FIG. 3A). The memory 309 has stored therein a sequence of numbers and a plurality of numerical ranges, wherein each numerical range is associated with a respective electrical load 130a, 130b, . . . 130n from the plurality of electrical loads 130.

The electrical appliance 100 further includes a plurality of switches 120. The plurality of switches 120 can be provided in the form of a plurality of solid state relays, such as a plurality of triodes for alternating current (TRIAC) and/or silicone controlled rectifiers (SCR). Each electrical switch 120a, 120b, . . . , 120n is electrically coupled to the power source 105, the controller 110, and a respective electrical load 130a, 130b, . . . , 130n from the plurality of electrical loads 130. Upon activation of one of the switches 120, the respective switch 120a, 120b, . . . , 120n provides an amount of power to the respective electrical load 130a, 130b, . . . 130n.

Referring to FIG. 3A there is shown a further functional block diagram of the electrical appliance 100 with specific details being shown in relation to the controller 110.

As seen in FIG. 3A, the controller 110 has a processing unit (or processor) 305 which is bi-directionally coupled to an internal storage module 309. The storage module 309 may be formed from non-volatile semiconductor read only memory (ROM) 360 and semiconductor random access memory (RAM) 370, as seen in FIG. 3B. The RAM 370 may be volatile, non-volatile or a combination of volatile and non-volatile memory.

The electrical appliance 100 can include one or more user output devices 314 such as a display 314, for example a liquid crystal display (LCD) panel or the like. The one or more output devices can be configured for displaying graphical images on the display 314 in accordance with instructions received from the controller 110. The controller 110 may include or be connected to a display controller 110 to control the presentation of the graphical images by the one or more user output devices. However, it will be appreciated that the one or more user output devices may be less sophisticated, for example the one or more user output devices may be provided in the form of one or more light emitting diodes or the like.

The electrical appliance 100 also includes one or more user input devices 313. In one form, the one or more user input device can be formed by keys, a keypad or like controls. In some implementations, the one or more user input devices 313 may include a touch sensitive panel physically associated with the display 314 to collectively form a touch-screen. Such a touch-screen may thus operate as one form of graphical user interface (GUI) as opposed to a prompt or menu driven GUI typically used with keypad-display combinations. However, in some instances, the one or more user input devices may be less sophisticated taking the form of one or more buttons, switches, knobs, or the like.

In some examples, the electrical appliance 100 can include a communication interface 150 to enable to electrical appliance to transmit and/or receive data from a separate device. For example, the communication interface may be a wireless communication interface to allow the electrical appliance to wireless receive input from a wireless device.

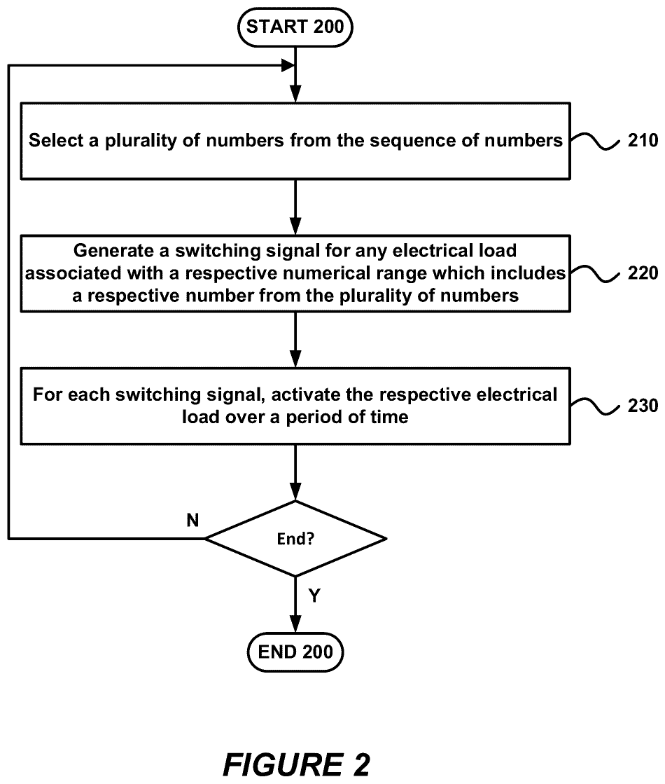

The methods described herein may be implemented, at least partially, using the embedded controller 110, where at least some of the steps of these methods may be implemented as one or more software application programs 333 executable within the embedded controller 110. With reference to FIG. 2, some of the steps of the described method 200 are implemented by instructions in the software 333 that are carried out within the controller 110. The software instructions may be formed as one or more code modules, each for performing one or more tasks. The software may also be divided into two separate parts, in which a first part and the corresponding code modules performs the described methods and a second part and the corresponding code modules manage a user interface between the first part and the user.

The software 333 of the embedded controller 110 is typically stored in the non-volatile ROM 360 of the internal storage module 309. The software 333 stored in the ROM 360 can be updated when required from a computer readable medium. The software 333 can be loaded into and executed by the processor 305. In some instances, the processor 305 may execute software instructions that are located in RAM 370. Software instructions may be loaded into the RAM 370 by the processor 305 initiating a copy of one or more code modules from ROM 360 into RAM 370. Alternatively, the software instructions of one or more code modules may be pre-installed in a non-volatile region of RAM 370 by a manufacturer. After one or more code modules have been located in RAM 370, the processor 305 may execute software instructions of the one or more code modules.

The application program 333 is typically pre-installed and stored in the ROM 360 by a manufacturer, prior to distribution of the electrical appliance 100. The second part of the application programs 333 and the corresponding code modules mentioned above may be executed to implement one or more graphical user interfaces (GUIs) to be rendered or otherwise represented upon the display 314 of FIG. 3A. Through manipulation of the user input device 313 (e.g., the keypad), a user of the appliance 100 and the application programs 333 may manipulate the interface in a functionally adaptable manner to provide controlling commands and/or input to the applications associated with the GUI(s).

FIG. 3B illustrates in detail the embedded controller 110, also shown as 302, having the processor 305 for executing the application programs 333 and the internal storage 309. The internal storage 309 comprises read only memory (ROM) 360 and random access memory (RAM) 370. The processor 305 is able to execute the application programs 333 stored in one or both of the connected memories 360 and 370. When the electrical appliance 100 is initially powered up, a system program resident in the ROM 360 is executed. The application program 333 permanently stored in the ROM 360 is sometimes referred to as “firmware”. Execution of the firmware by the processor 305 may fulfil various functions, including processor management, memory management, device management, storage management and user interface.

The processor 305 typically includes a number of functional modules including a control unit (CU) 351, an arithmetic logic unit (ALU) 352, a digital signal processor (DSP) 353 and a local or internal memory comprising a set of registers 354 which typically contain atomic data elements 356, 357, along with internal buffer or cache memory 355. One or more internal buses 359 interconnect these functional modules. The processor 305 typically also has one or more interfaces 358 for communicating with external devices via system bus 381, using a connection 361.

The application program 333 includes a sequence of instructions 362 though 363 that may include conditional branch and loop instructions. The program 333 may also include data, which is used in execution of the program 333. This data may be stored as part of the instruction or in a separate location 364 within the ROM 360 or RAM 370.

In general, the processor 305 is given a set of instructions, which are executed therein. This set of instructions may be Organized into blocks, which perform specific tasks or handle specific events that occur in the electrical appliance 100. Typically, the application program 333 waits for events and subsequently executes the block of code associated with that event. Events may be triggered in response to input from a user, via the user input devices 313 of FIG. 3A, as detected by the processor 305. Events may also be triggered in response to other sensors 140 and interfaces in the electrical appliance 100.

The execution of a set of the instructions may require numeric variables to be read and modified. Such numeric variables are stored in the RAM 370. The disclosed method uses input variables 371 that are stored in known locations 372, 373 in the memory 370. The input variables 371 are processed to produce output variables 377 that are stored in known locations 378, 379 in the memory 370. Intermediate variables 374 may be stored in additional memory locations in locations 375, 376 of the memory 370. Alternatively, some intermediate variables may only exist in the registers 354 of the processor 305.

The execution of a sequence of instructions is achieved in the processor 305 by repeated application of a fetch-execute cycle. The control unit 351 of the processor 305 maintains a register called the program counter, which contains the address in ROM 360 or RAM 370 of the next instruction to be executed. At the start of the fetch execute cycle, the contents of the memory address indexed by the program counter is loaded into the control unit 351. The instruction thus loaded controls the subsequent operation of the processor 305, causing for example, data to be loaded from ROM memory 360 into processor registers 354, the contents of a register to be arithmetically combined with the contents of another register, the contents of a register to be written to the location stored in another register and so on. At the end of the fetch execute cycle the program counter is updated to point to the next instruction in the system program code. Depending on the instruction just executed this may involve incrementing the address contained in the program counter or loading the program counter with a new address in order to achieve a branch operation.

Each step or sub-process in the processes of the methods described below is associated with one or more segments of the application program 333, and is performed by repeated execution of a fetch-execute cycle in the processor 305 or similar programmatic operation of other independent processor blocks in the electrical appliance 100.

Operation of the electrical appliance 100 is herein described with reference to FIG. 2. At step 210, the method 200 includes the controller 110 selecting a plurality of numbers from the sequence of numbers stored in memory 309. The plurality of numbers are a portion of the total sequence of numbers. The plurality of numbers includes n numbers such that a maximum power consumption of simultaneous activation of n electrical loads 130 from the plurality of electrical loads 130 does not exceed a power threshold for the electrical appliance 100.

At step 220, the method 200 includes generating, by the controller 110, a switching signal for any electrical load 130a, 130b, . . . 130n from the plurality of electrical loads 130 which is associated with a respective numerical range may include (i.e. encompasses) a number from the plurality of numbers. In some instances, the numerical ranges may not encompass any number from the plurality of numbers resulting in no switching signal being generated.

At step 230, the method 200 includes activating, for each switching signal, a respective switch 120a, 120b, . . . , 120n of the plurality of switches 120 to electrically connect the respective electrical load 130a, 130b, . . . 130n to the power source 105 over a period of time.

It will be appreciated that whilst the above method 200 has been described performing iterations, it is possible that a single iteration can be performed by the controller.

Advantageously, the described method uses less memory compared with previous methodologies which utilized lookup tables. As will be described in further embodiments below, using a mathematical function can simplify the generation of the sequence of numbers thereby avoiding the difficult process of generating the lookup table.

In a particular form, the sequence of numbers is a sequence of tuples. The numbers may be integers, decimals or fractions represented by an integer or floating-point data structure. Each tuple is a data structure including multiple parts. For example, a tuple may be an array, a dictionary, or other similar data structures. Each part of the tuple is a tuple element such that each tuple includes a plurality of tuple elements. The plurality of numbers is a plurality of tuple elements of the respective tuple selected from the sequence of tuples. Each tuple includes n tuple elements, wherein n is set to a maximum number of electrical loads 130 which can be operative simultaneously without exceeding a power threshold.

In certain embodiments, the sequence of numbers is stored in a non-volatile manner in the memory. The sequence of numbers can be stored in the memory at the time of manufacture. However, in other embodiments, the sequence of numbers is dynamically generated by the processor 305 and stored in a volatile manner in the memory. More specifically, the sequence of number can be dynamically generated by the processor 305 in response to the electrical appliance 100 receiving input to begin operation (e.g. the electrical appliance 100 includes a heater element which receives user input to begin heating, wherein the controller 110 generates the sequence of numbers in response to receiving the user input to begin heating) or in response to the electrical appliance 100 being activated for future operation (e.g. the electrical appliance 100 is electrically turned on, wherein the sequence of numbers is generated upon startup).

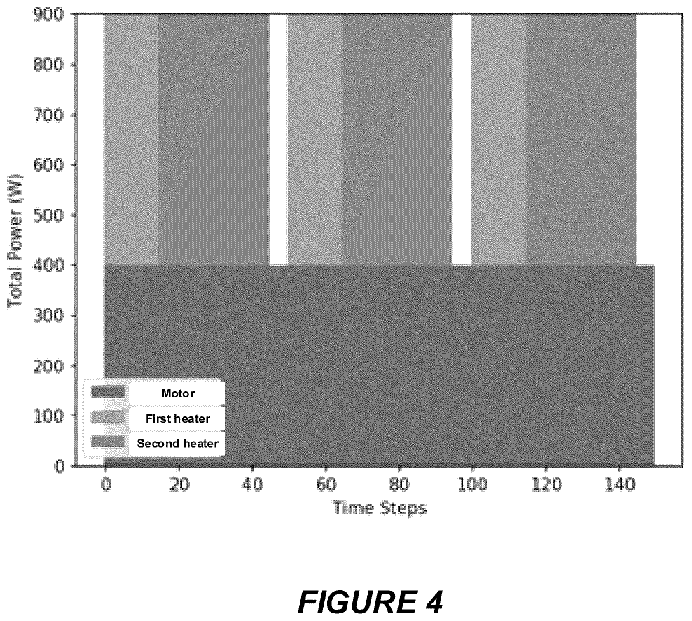

Exemplary operation of the electrical appliance of FIG. 1 using the method described in relation to the method 200 will herein be described with reference to the graph depicted in FIG. 4.

In this example, the exemplary electrical appliance 100 includes a first and second heater that each draw a maximum of 500 Watts, and a motor that draws a maximum of 400 Watts. The electrical appliance 100 has a total power consumption restraint where the electrical appliance 100 cannot exceed 1000 Watts. One or more input devices of the electrical appliance 100 are used by the user to indicate that the electrical appliance 100 is to operate in a manner the first heater draws an average power over time of 150 Watts, the second heater draws an average power over time of 300 Watts, and the motor draws an average power over time of 400 Watts. In this example, the electrical loads 130 of the first and second heater and the motor can be selectively activated or deactivated for each half-cycle of the alternating power source 105. A sequence of numbers is partitioned into numerical ranges, wherein a first numerical range is associated with the first heater, a second numerical range is associated with the second heater, the motor is associated with the third numerical range, and a fourth numerical range is not associated with any electrical load 130a, 130b, . . . 130n. In this example, for any given half-cycle, zero, one, or two electrical loads 130 can turned on simultaneously. As the electrical device is being electrically powered by a 50 Hz alternating power source 105 and the electrical loads 130 can be switched on or off during each half cycle (i.e. 2 switching points per cycle), 100 (i.e. 50×2) different values of numbers of the sequence of numbers can be defined. Therefore, the sequence of numbers S₁ can be defined in groups or tuples, where each group or tuple includes two numbers selected from a numerical range between 0 to 99 (i.e. 100 values), such as that shown by way of example according to Sequence 1 below:

$${S}_{1} = \{ ( 0 , 50 ) , ( 1 , 51 ) , ( 2 , 52 ) , … , ( 49 , 99 ) \} = {\{ ( i , i + 50 ) \}}_{i = 0}^{49} , \qquad Sequence 1$$

In this example sequence, each second tuple element of a tuple is equal to the respective first tuple element of the respective tuple incremented by an offset constant, which in this example the offset constant is equal to 50 and can be stored in memory. Each tuple includes a plurality of tuple elements, wherein the first element is a fixed number which increases from 0) to 49 and the second element of each tuple increases by an offset constant of 50 relative to the first element of the respective tuple.

The numerical ranges can be set by the processor 305 of the controller 110 in memory based on the desired input from the user provided via the one or more input devices. In this instance, given the above average power required for each electrical load 130a, 130b, . . . 130n, the processor 305 can set in memory the numerical ranges in the following manner: first numerical range: [0, 15): second numerical range: [15, 45); and a third numerical range: [45, 95), where “[” or “]” indicates inclusive and “(” or “)” indicates not-inclusive. For example, the first numerical range includes 0 to 14 but does not include 15 and above.

Based on the above, the processor 305 is configured to select, in sequential order per each time step (i.e. each half cycle of the alternating power source 105), a tuple from the sequence of tuples and determine the respective numerical range which includes each tuple element of the selected tuple. For example, the processor 305 can be configured to initially select the first tuple of the sequence of tuples which is a pair (0, 50). The first tuple element of 0) falls within the first numerical range which is associated with the first heater. The second tuple element of 50 falls within the third numerical range which is associated with the motor. This results in the first heater and the motor being activated for the first half cycle of the alternating power source 105. The second tuple, (1, 51), provides the same result wherein the first heater and the motor are activated for the second half cycle of the alternating power source 105. Cycling over these 50 tuples of the sequence of tuples provides an average power of 150 Watts for the first heater, 300 Watts for the second heater, and 400 W for the motor as shown in FIG. 4.

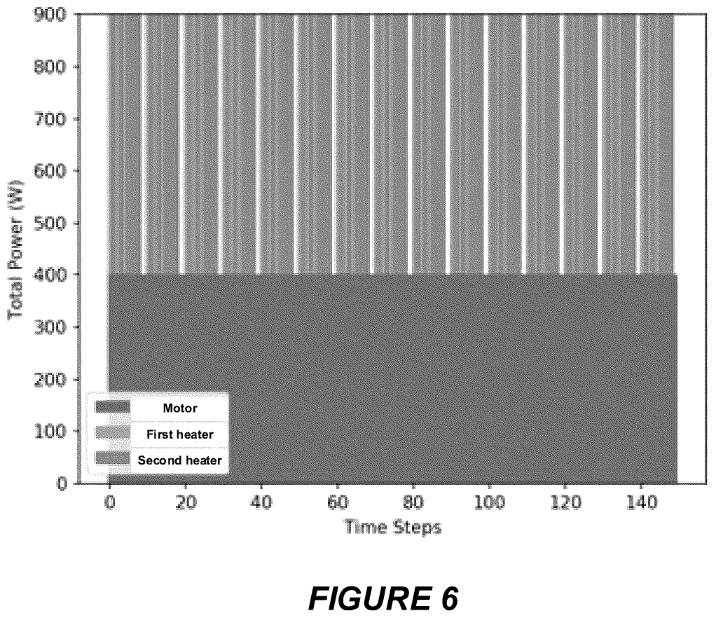

Exemplary operation of the electrical appliance 100 of FIG. 3 using the method described in relation to the method 200 and utilizing a second switching technique will herein be described with reference to the graph depicted in FIG. 6. This example will be based on the exemplary electrical appliance 100 described earlier, however will be configured to minimize flicker. In this example, the tuples of the sequence of tuples S₁ are reordered to reduce flickering to define a sequence of tuples S₂ as defined in Sequence 2:

$${S}_{2} = \{ ( 0 , 50 ) , ( 25 , 75 ) , ( 5 , 55 ) , … , ( 24 , 74 ) , ( 49 , 99 ) \} = {\{ ( {x}_{i} , {x}_{i} + 50 ) \}}_{i = 0}^{49} , \qquad Sequence 2$$

A low-discrepancy or pseudo-random sequence can be used directly or indirectly to reorder the sequence of tuples S₁ to reduce flickering to define the sequence of tuples S₂. In the event that the low-discrepancy or pseudo-random sequence is used indirectly, the low-discrepancy or pseudo-random sequence can be used to reorder an increasing sequence as exemplified by Sequence 2 or the low-discrepancy or pseudo-random sequence can be used directly as exemplified in Sequence 3 discussed later in this document. In one example, the low-discrepancy or pseudo-random sequence may be a base-5 Halton sequence.

It will be appreciated that S₂ has all the same pairs as S₁ but are reordered to reduce flickering. For S₁, the short-term flicker severity is 1.1 but after reordering, the short term flicker severity for S₂ is 0.8 using the same numerical ranges as defined above in relation to the earlier example. The resulting activation of the electrical loads 130 of the electrical appliance 100 alters the period of the summed power from 50 time steps to 10 time steps as shown in FIG. 6, thereby increasing the frequency of the consumed power of the electrical appliance 100 which in turn results in reducing human-perceivable flickering for any lights which are connected to the mains power source for the electrical appliance 100.

In one form, the sequence of numbers is based on a multi-dimensional low-discrepancy sequence. For example, the low-discrepancy sequence is a base-n Halton sequence. However, in other instances, the sequence of tuples is based on stochastic or pseudo-random sequence. In one specific form, the first tuple element of each tuple is based on a selected element of the base-n Halton sequence and a subsequent tuple element of the respective tuple is offset from the first tuple element by an offset constant. The first tuple element is equal to a multiplier constant multiplied by the selected element of the base-n Halton sequence. Advantageously, using a mathematical sequence, such as the Halton sequence, can simplify the generation of the sequence of numbers thereby avoiding the difficult process of generating a lookup table, particularly when there may be a high number of electrical loads that may need to be simultaneously activated.

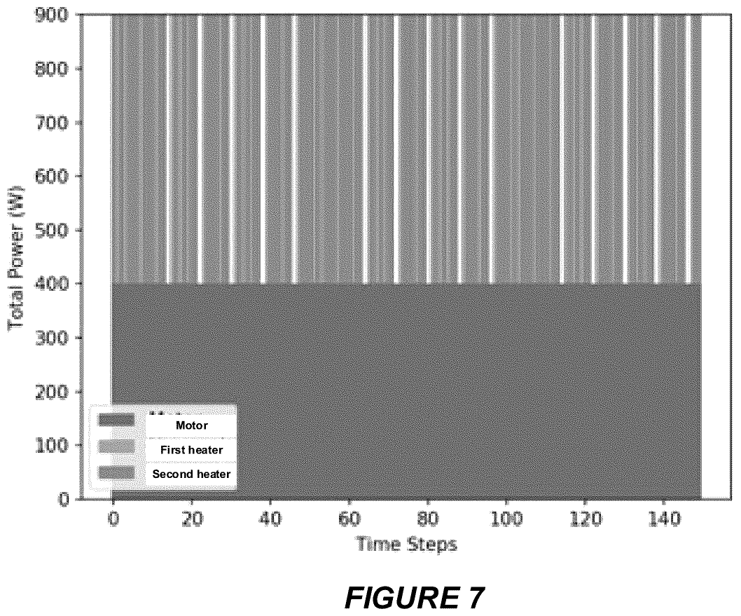

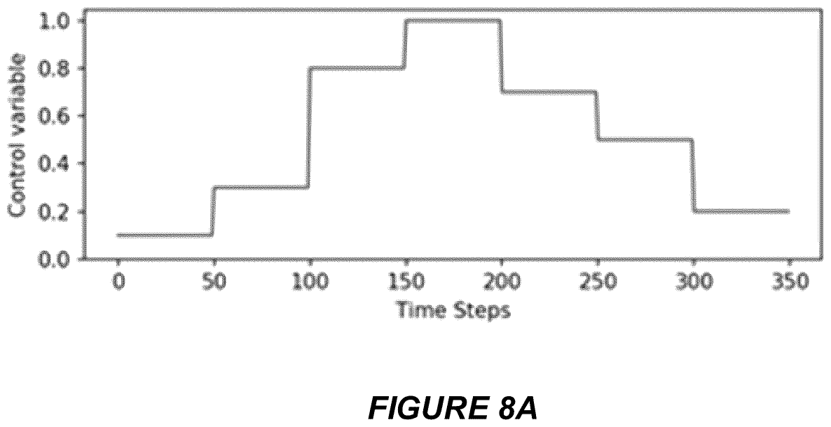

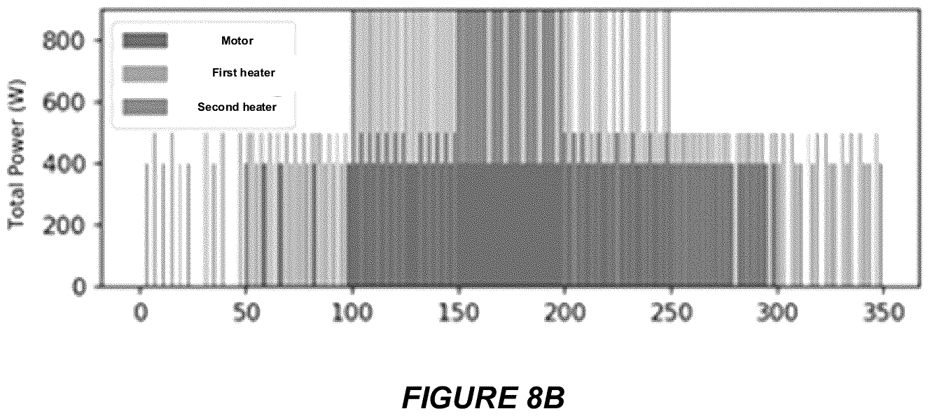

Exemplary operation of the electrical appliance 100 of FIG. 3 using the method described in relation to the method 200 and utilizing a third switching technique based on the Halton sequence will herein be described with reference to the graphs depicted in FIGS. 7, 8A and 8B. In particular, the sequence of tuples, S₃, may be defined by Sequence 3 below:

$${S}_{3} = \{ ( 25 , 75 ) , ( 12 , 62 ) , ( 38 , 88 ) , … , ( 22 , 77 ) , ( 15 , 65 ) \} = {\{ ( {s}_{i} , {s}_{i} + 50 ) \}}_{i = 0}^{49} , \qquad Sequence 3$$

where sᵢ is fifty multiplied by a base-2 Halton sequence that is rounded, as expressed in Sequence 4 below:

$${s}_{i} = ⌊ 50 H ( i + 1 , 2 ) + 0.5 ⌋ \qquad Sequence 4$$

Applying the same numerical ranges and method as described in earlier examples of the electrical appliance 100 results in the same power distribution between the heaters and motor but provides a less regular pattern. In particular, a more pseudo-random pattern is provided as shown in FIG. 7 utilizing the sequence of tuples as defined by S₃ that can be considered less noticeable to a human user. The short term flicker severity for S₃ is 0.9 which is greater than S₂ but is still lower than the short term flicker severity of S₁.

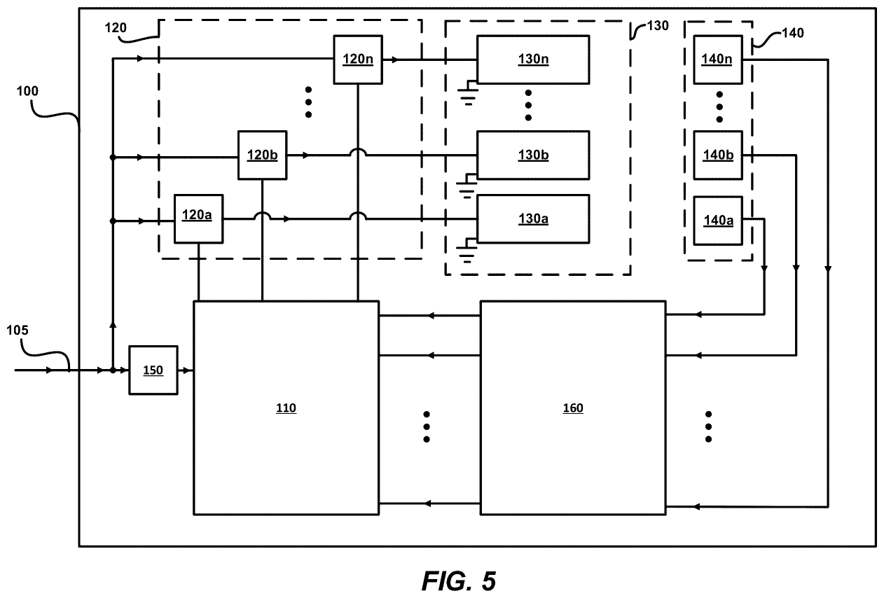

Whilst the specific ratio or percentages of the numerical ranges can be defined based on the one or more user inputs for operating the one or more electrical loads 130, in one particular form, the numerical ranges stored in memory of the controller 110 may be dynamically scaled based on feedback signals received from the one or more sensors associated with the plurality of loads 130. For example, the processor 305 can be configured to dynamically scale the plurality of numerical ranges based on one or more PID control variables generated by a PID controller 160 as discussed in relation to the embodiment depicted by FIG. 5 as discussed below. More specifically, this is exemplified in FIGS. 8A and 8B, where FIG. 8A shows a control variable generated by the PID controller 160 which varies over time and FIG. 8B shows the power consumed by the plurality of electrical loads 130 over the same period of time and utilizing the sequence of tuples, S₃, discussed above. In this particular example, the control variable is multiplied against the numerical ranges for the first to third numerical ranges. However, in this example, the remaining numerical range is not scaled by the control variable.

It will be appreciated that either the processor 305 of the controller 110 of the electrical appliance 100 can generate the sequence of tuples or a separate processing system can be used to generate the sequence of tuples, wherein the sequence of tuples is transferred to and stored in memory of the electrical appliance 100. In a generic manner, the sequence of tuples, can be defined according to Sequence 5 provided below:

$$S = {\{ ( {s}_{i , 0} , {s}_{i , 1} , … , {s}_{i , k - 1} ) \}}_{i = 0}^{N} \qquad Sequence 5$$

where the length of the tuple k corresponds to the maximum number of electrical loads 130 that can draw power without exceeding a predetermined maximum power threshold. Then at timestep M, let 0≤j=M mod N<N and a particular electrical load 130a, 130b, . . . 130n is switched on if αₗ≤s_{j,r}<bₗ for any r=0,1, . . . , k−1 and off otherwise. In the instance of multiple electrical loads 130, αₗ, bₗ are set such that bₗ≤αₗ₊₁. As such, k or fewer electrical loads 130 can draw power at any timestep thus preventing the total maximum power consumption exceeding the predetermined maximum power threshold.

In instances where the sequence of tuples has a length, L, and a numerical range Rₗ=[αₗ, bₗ=α_{l+L}), the length of the numerical range is approximately proportional to the fraction of time that the load(s) 130 is/are switched on.

In instances where the sequence of tuples has a length, L, and a numerical range Rₗ=[αₗ, bₗ=α_{l+L}) is approximately proportional to the power draw, several characteristics are in common which result in a reduction in human perceivable flicker from one or more lights sharing the same alternating power source 105. In particular, if s_{i,j} is set by the processor 305 of the controller 110 or by another processing system such that for Sα={s_{i,j}∈[α, α+L)}, S_{b}={s_{i,j}∈[b, b+L)}, and α<b, L>0, where a is at or above the minimum s_{i,j} and b+L is at or below the maximum, s_{i,j} has the following properties to minimize human perceivable flicker:
1. card(S_{α})≈card(S_{b}), where card denotes the cardinality or number of elements.
2. For I_{α}={i:s_{i,j}∈S_{α}}, I_{b}={i:s_{i,j}∈S_{b}}, then the values in I_{α} and I_{b} are spread across 0 to N−1.

In the example above in relation to S₁, this sequence of tuples satisfies property (1) but not property (2), while S₂ and S₃ satisfy both properties. There are many ways for the processor 305 of the appliance 100 or a separate processing system to set s_{i,j}, such as s_{i,j}=CH (ki+j,k), where C is a constant and H is a Halton sequence with base k. In another form, the processor 305 can be configured to use another common low-discrepancy sequence for either s_{i,j} or s_{i,0} with s_{i,j}=s_{i,0}+jD, for an appropriate value of D. In particular, S can be set to be a permutation of {iC}ᵢ₌₀^{N-1}. For example, elements can be randomly permutated by the processor 305 until the elements satisfy a measurement of tuple spread, such as

$${min}_{0 \leq i < N - 1} \vert {s}_{i + 1 , 0} - {s}_{i , 0} \vert > M or {\sum }_{j = 1}^{r} {c}_{j} {min}_{0 \leq i < N - 1} \vert {s}_{i + j , 0} - {s}_{i , 0} \vert > M$$

$$where {s}_{i + N , 0} = {s}_{i , 0} .$$

As the controller 110 can be configured to sequentially progress through the sequence of tuples in order (i.e. sequential order), once the processor 305 processes the last tuple in the sequence, the processor 305 can return to the first tuple in the sequence of tuples. Thus, the activation signals that are generated can repeat during multiple iterations over the length of the sequence of tuples.

Referring to FIG. 5 there is shown a further schematic diagram of another example of the electrical appliance 100 which is configured to reduce or eliminate human-perceivable flicker. In particular, the controller 110 of the electrical appliance 100 is configured to generate the one or more activation signals to control switching of the high power electrical loads 130 for reducing voltage/current fluctuation in the associated power mains that can cause visible/observable flickering of lights which share the alternating power source 105. Factors that have been identified as affecting flicker of lights that are observable (or visible) to a human include: (a) the sum of all artefacts caused by each respectively actively switched loads 130 cause combined artefacts to be introduced to (or present on) the mains power source or circuit; and (b) the artefacts introduced to (or present on) the mains power source or circuit can cause variation in light intensity that occur at a frequency that can be observed: and (c) a person cannot typically perceive visual events occurring at a frequency greater than a human-perceivable flicker frequency threshold. To address this issue, the electrical appliance 100 further includes a zero-crossing detector 150. The controller 110 is configured to activate at least some of the one or more electrical loads 130 for a respective iteration in response receiving a zero-crossing detection signal indicative a zero-crossing event for the alternating power source 105. By configuring the appliance 100 of FIG. 5 to control zero crossing switching of high power loads 130, such that short term flicker severity is less than or equal to 1.0, flicker observed from one or more lights connected to the same power source or circuit can be eliminated or at least reduced. The short-term flicker severity is an electric power quality index defined by the International Electrotechnical Commissioner (IEC), specifically International Standard IEC 61000-4-15. Avoiding frequency components which result in a short term flicker severity greater than 1.0, reduces or eliminates artefacts introduced to (or overlayed on) the power source or circuit—thereby a person would not observe flickering of lights connected (either internally or externally) to a related power circuit.

Referring more specifically to FIG. 5 where like components between FIGS. 1 and 5 use the same reference number, the electrical appliance 100 includes the plurality of electrical loads 130. Each electrical load 130a, 130b, . . . 130n is selectively powerable from the common alternating power source 105. The electrical appliance 100 further includes the controller 110 including the processor 305 (see FIG. 3A) coupled to the memory 309 (see FIG. 3B). The memory 309 has stored therein the sequence of numbers and the plurality of numerical ranges, wherein each respective electrical load 130a, 130b, . . . 130n from the plurality of electrical loads 130 is associated with a particular numerical range. The appliance 100 further includes a plurality of switches 120. In a non-limiting example, the plurality of switches 120 can be provided in the form of a plurality of solid-state relays, such as a plurality of triodes for alternating current (TRIAC) and/or silicone controlled rectifiers (SCR). Each electrical switch 120a. 120b, . . . , 120n is electrically coupled to the alternating power source 105, the controller 110, and a respective electrical load 130a, 130b . . . , 130n from the plurality of electrical loads 130.

The electrical appliance 100 of FIG. 5 further includes a zero-crossing detector 150 which is electrically coupled to the alternating power source 105 and the controller 110. The zero-crossing detector 150 is configured to detect a zero-crossing event of the alternating power source 105 and transfer a detection signal to the controller 110. The controller 110 is configured to generate the one or more activation signals in response to receiving the zero-crossing detection signal. The zero-crossing detector 150 can be provided in the form of a zero crossing circuit which can be an electrical circuit that detects the input AC power source at phases close to zero degrees or 180 degrees, thereby enabling the controller to activate one or more of the switches 120 to provide each half cycle of the AC waveform to be selectively passed to or restricted from a selection of the plurality of electrical loads 130. The purpose of the circuit is to start conducting while the voltage is crossing zero volts, such that the output voltage is in complete sine-wave half-cycles.

The electrical appliance 100 of FIG. 5 further includes a one or more sensors for monitoring an operation of the electrical appliance. In some embodiments, one or more sensors can monitor one or more electrical loads 130. In certain examples where one of the electrical loads 130 is a heating element, the associated sensor may be a temperature sensor which is configured to measure a temperature in a cooking chamber associated with heating element. In instances where one of the electrical loads 130 is a motor, the associated sensor may be a tachometer configured to measure revolutions performed by the motor.

The electrical appliance 100 of FIG. 5 is particularly relevant to switching of high-powered loads 130, such as high-powered resistive heating elements, because high power loads 130 result in current and/or voltage changes on the power line. In this embodiment, the appliance 100 is configured to control a temperature using the one or more heating elements. It will be appreciated that feedback control of temperature can be implemented using any conventional or known feedback methods including, but not limited to, On-Off Control, Proportional Control, Proportional-Derivative Control, Proportional-Integral Control, Proportional-Integral-Derivative Control (PID control), and Third-Order Control Systems. As shown in FIG. 5, the electrical appliance 100 can further include a PID controller 160 which is electrically connected to the controller 110 and the plurality of sensors. However, it will be appreciated that the controller 110 can be configured to implement a PID control program and thus act as the PID controller without having a separate and dedicated hardware device for performing this task. In this embodiment, the PID controller 160 receives one or more sensor measurements from the one or more sensors. The PID controller 160 generates one or more control variables using the one or more sensor measurements. The one or more control variables are then transferred to the controller 110. In one form, the processor 305 of the controller 110 is configured to dynamically scale the plurality of numerical ranges based on one or more PID control variables, wherein the one or more PID control variables are based on one or more input signals received by the processor 305. The one or more user input devices discussed in relation to the electrical appliance 100 of FIG. 1 which are also present in relation to the electrical appliance 100 of FIG. 5 allow for the user to provide input to set one or more set points for one or more of the electrical loads 130. The controller 110 can transfer an electrical signal indicative of each set point to the PID controller 160 for generating the one or more control variables.

It will be appreciated that a different sequence of numbers may be utilized by the appliance 100 depending upon the frequency of the AC power source (i.e. 50 Hz compared to 60 Hz).

It will be appreciated that it is also possible to modulate the switching signal so that the load 130a, 130b, . . . 130n is switched on or off for full cycles rather than half cycles resulting from the zero-crossing detector 150.

In certain aspects, the appliance 100 is a kitchen appliance and at least some of the high power electrical loads 130 may be a heating element of the kitchen appliance. However, it will be appreciated that the appliance 100 may include different types of electrical loads 130. For example, an example electrical appliance 100 may include one or more heating elements and one or more motors. In one particular form, the kitchen appliance 100 may be a multi-function kitchen countertop appliance which can operate on electrical circuits used by other appliances and lights.

In one form, the plurality of electrical loads can include a larger electrical load having a maximum power consumption which is a multiple (i.e., an integer multiple) of a smaller maximum power consumption of each remaining smaller electrical load within the plurality of electrical loads. In this instance, the larger electrical load can be represented as multiple smaller electrical loads, wherein the method described above can be performed by the processor based on the larger electrical load being multiple smaller electrical loads, wherein each smaller electrical load has the smaller maximum power consumption.

It will be appreciated that, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

Unless the context clearly requires otherwise, throughout the description and the claims, the words “comprise”, “comprising”, and the like are to be construed in an inclusive sense as opposed to an exclusive or exhaustive sense: that is to say, in the sense of “including, but not limited to”.

Similarly, it is to be noticed that the term “coupled”, when used in the claims, should not be interpreted as being limitative to direct connections only. The terms “coupled” and “connected”, along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment, but may refer to the same embodiment. Furthermore, the particular features, structures or characteristics may be combined in any suitable manner, as would be apparent to one of ordinary skill in the art from this disclosure, in one or more embodiments.

Similarly it will be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description. Although the invention has been described with reference to specific examples, it will be appreciated by those skilled in the art that the invention may be embodied in many other forms.

It will be appreciated that an embodiment of the invention can consist essentially of features disclosed herein. Alternatively, an embodiment of the invention can consist of features disclosed herein. The invention illustratively disclosed herein suitably may be practiced in the absence of any element which is not specifically disclosed herein.

1. An electrical appliance comprising:
a plurality of electrical loads, each electrical load being powered from a common power source;
a controller including a processor coupled to a memory, wherein the memory has stored therein a sequence of numbers and a plurality of numerical ranges, each numerical range being associated with a respective electrical load from the plurality of electrical loads; and
a plurality of switches, each electrical switch being electrically coupled to the power source, the controller, and a respective electrical load of the plurality of electrical loads;
wherein the appliance is configured to iteratively:
select, by the controller, a plurality of numbers from the sequence of numbers;
generate, by the controller, a switching signal for any electrical load of the plurality of electrical loads which is associated with a respective numerical range which includes a number from the plurality of numbers; and
activate, for each switching signal, a respective switch of the plurality of switches to electrically connect the respective electrical load to the power source over a period of time.

2. The electrical appliance according to claim 1, wherein the plurality of numbers includes n numbers such that a maximum power consumption via simultaneous activation of n electrical loads from the plurality of electrical loads does not exceed a power threshold for the electrical appliance.

3. The electrical appliance according to claim 1, wherein the sequence of numbers is a sequence of tuples.

4. The electrical appliance according to claim 3, wherein each tuple includes n tuple elements.

5. The electrical appliance according to claim 4, wherein the sequence of numbers is generated based on a low-discrepancy sequence.

6. The electrical appliance according to claim 5, wherein the low-discrepancy sequence is a base-n Halton sequence.

7. The electrical appliance according to any one of claims 3 to 6, wherein the sequence is based on a stochastic or pseudo-random sequence.

8. The electrical appliance according to any one of claims 1 to 7, wherein the sequence of numbers is stored in a non-volatile manner in the memory.

9. The electrical appliance according to any one of claims 1 to 8, wherein the sequence of numbers is dynamically generated by the processor and stored in a volatile manner in the memory.

10. The electrical appliance according to any one of claims 1 to 9, wherein electrical power consumed by the electrical appliance has a short term flicker severity of less than or equal to 1.0.

11. The electrical appliance according to any one of claims 1 to 10, wherein the appliance includes one or more user input devices for setting operation of at least some of the electrical loads of the plurality of loads, wherein the processor is configured to dynamically scale the plurality of numerical ranges based on one or more input signals generated by the one or more user input devices.

12. The electrical appliance according to claim 11, wherein the controller is configured to dynamically scale the plurality of numerical ranges based on one or more PID control variables generated by a PID controller, wherein the PID controller is part of the controller or in electrical communication with the controller.

13. The electrical appliance according to claim 12, wherein the plurality of electrical loads include one or more heating elements, wherein the electrical appliance further includes one or more temperature sensors for measuring a temperature of an object or medium heated by at least some of the one or more heating elements, wherein the one or more input signals include one or more temperature measurement signals generated by the one or more temperature sensors.

14. The electrical appliance according to claim 12 or 13, wherein the plurality of electrical loads include one or more motors, wherein the electrical appliance further includes one or more tachometers for at least some of the one or more motors, wherein the one or more input signals include one or more tachometer measurement signals generated by the one or more tachometers.

15. The electrical appliance according to any one of claims 1 to 14, wherein the electrical appliance further includes a zero-crossing detector, wherein the controller is configured to activate, for each switching signal, the respective switch of the plurality of switches in response to receiving a zero-crossing detection signal from the zero-crossing detector.

16. The electrical appliance according to claim 15, wherein the controller is configured to iteratively select a plurality of numbers from the sequence of numbers in response to each zero-crossing detection signal.

17. The electrical appliance according to any one of claims 1 to 16, wherein the plurality of numerical ranges is set by the processor based on a current configuration of the electrical appliance.

18. The electrical appliance according to any one of claims 1 to 17, wherein the electrical application is a kitchen appliance.

19. An electrical appliance comprising:
a controller including a processor coupled to a memory, wherein the memory has stored therein a sequence of numbers and a plurality of numerical ranges;
a plurality of electrical load elements, wherein at least one of the plurality of electrical load elements is associated with one of the stored plurality of numerical ranges, wherein the controller is configured to:
read a first portion of the sequence, wherein the first portion comprises at least one number,
determine the numerical range in which the first portion of the sequence falls therein, and
based on the determination, selectively power at least one of the electrical load elements.

20. The electrical appliance according to claim 19, wherein the sequence of numbers is a sequence of tuples.

21. The electrical appliance according to claim 20, wherein the sequence of numbers is generated based on a low-discrepancy sequence.

22. The electrical appliance according to claim 21, wherein the low-discrepancy sequence is a Halton sequence.

23. The electrical appliance according to claim 22, wherein the Halton sequence is a base n, Halton sequence, wherein n is equal to a number of electrical loads within the plurality of electrical loads.

24. The electrical appliance according to any one of claims 19 to 23, wherein the sequence of numbers is stored in a non-volatile manner in the memory.

25. The electrical appliance according to any one of claims 19 to 24, wherein the sequence of numbers is dynamically generated by the processor and stored in a volatile manner in the memory.

26. The electrical appliance according to any one of claims 19 to 25, wherein a second portion of the sequence of numbers is sequentially read at a next zero crossing point.

27. The electrical appliance according to any one of claims 19 to 25, wherein a second portion of the sequence of numbers, comprising at least one number, is sequentially read after predetermined time period has elapsed.

28. The electrical appliance according to any one of claims 19 to 27, wherein the sequence is associated with a short-term flicker severity of less than 1.0.

29. The electrical appliance according to any one of claims 18 to 28, wherein the plurality of numerical ranges is fixed.

30. The electrical appliance according to any one of claims 18 to 28, wherein the plurality of numerical ranges is set by the processor, based on a current configuration of the electrical appliance.
